(19) United States
(12) Patent Application Publication
(10) Pub. No.: US 2002/0106863 A1
(43) Pub. Date: Aug. 8, 2002

(54) Method for fabricating semiconductor devices

(76) Inventors: Seung-Hoon Sa, Chungchungbuk-do (KR); In-Chul Jung, Daegu (KR)

Correspondence Address: MARSHALL, GERSTEIN & BORUN, 6300 SEARS TOWER, 233 SOUTH WACKER, CHICAGO, IL, 60606-6357, US

(21) Appl. No.: 09/934,179

(22) Filed: Aug. 21, 2001

(30) Foreign Application Priority Data
Aug. 28, 2000 (KR) 2000-50185

(51) Int. Cl. H01L 21/76

(52) U.S. Cl. 438/410

(57) ABSTRACT

A method for fabricating a semiconductor device which can improve the operational characteristics of the device by preventing the deactivation of dopants caused by a supplementary thermal treatment. The method for fabricating a semiconductor includes: defining an active region by forming a device isolation layer on a semiconductor substrate; forming a gate electrode in the active region and forming a LDD region on the surface of the substrate at both sides of the gate electrode; forming a gate sidewall at the sides of the gate electrode and forming a silicide layer on the top surface of the gate electrode and the exposed surface of the substrate; implanting impurity ions for forming a source/drain by using the gate electrode as a mask; and activating the impurity ions for forming a source/drain by annealing after forming first and second dielectric layers on the whole surface of the substrate.

### BACKGROUND

1. Technical Field

A semiconductor device, and more particularly, a method for fabricating a semiconductor device which can improve the operational characteristics of the device by preventing the deactivation of dopants caused by an additional thermal treatment are disclosed.

2. Description of the Related Art

A fabricating process of a semiconductor device according to the conventional art will now be described with reference to the accompanying drawings.

Figures la through le are cross-sectional views of a fabricating process of a semiconductor device according to the conventional art. Figures la through lc illustrate a step for forming a source/drain junction and a step for forming a silicide layer in a process for fabricating a DRAM and a LOGIC device.

Specifically, as illustrated in Figure la, a device isolation layer 2 is formed in a device isolation region of a semiconductor substrate 1 by a STI or LOCOS process. Continually, a gate oxide layer 3 and a gate electrode 4 are formed in an active region defined by the device isolation layer 2, and then an ion implantation step for forming a LDD region 8 is carried out. Then, a gate sidewall 5 is formed at sides of the gate electrode 4.

As illustrated in Figure lb, an ion implantation step for forming a source/drain region is carried out.

As illustrated in Figure lc, a RTP(Rapid Thermal Process) annealing step for activating a source/drain region 7 is then carried out. As illustrated in Figure ld, a metal silicide layer 8 is then formed on the surface of the source/drain region 7 and the surface of the gate electrode 4 by forming a cobalt layer on the front surface as a material layer for silicide layer formation and carrying out the silicide step by annealing. As illustrated in Figure le, an ILD(inter-layer dielectric) layer 9 and a BPSG(boron phosphorus silicate glass) layer 10 are then formed in that order, and a RTP annealing step for reflowing the BPSG layer 10 is carried out.

In each fabricating process according to the conventional art, the activation and deactivation of dopants occurs using an additional thermal treatment, which is characterized as follows. In order to reduce damage in the ion implantation step for forming a source/drain region in Figure lb, the high temperature thermal treatment of Figure lc is necessary. At this time, the activation of dopants is carried out to ensure that the device has a low resistance. However, the dopants activated by the additional thermal treatment are deactivated again during the steps in Figures ld and le to resulting in an increase in the resistance of an ion-implanted region or make polycrystalline material used as a gate unstable, thereby affecting the device characteristics.

Therefore, the above-described fabricating process of a semiconductor device according to the conventional art has the following problem. Due to the deactivation of dopants caused by the additional thermal treatment, the resistance of the ion-implanted region is increased, or the poly used as a gate is made unstable, for thereby affecting the device characteristics.

In addition, to solve this problem, although the annealing step to be carried out after the deposition of an ILD and BPSG layer is carried out within the limits of a temperature range lower than the previous annealing temperature, this also makes the final resistance higher than the initial resistance.

### SUMMARY OF THE DISCLOSURE

A method for fabricating a semiconductor device is disclosed which can improve the operational characteristics of the device by preventing the deactivation of dopants caused by a supplementary thermal treatment is disclosed.

A method for fabricating a semiconductor device according to the disclosure, includes: defining an active region by forming a device isolation layer on a semiconductor substrate; forming a gate electrode in the active region and forming a LDD region on the surface of the substrate at both sides of the gate electrode; forming a gate sidewall at the sides of the gate electrode and forming a silicide layer on the top surface of the gate electrode and the exposed surface of the substrate; implanting impurity ions for forming a source/drain by using the gate electrode as a mask; and activating the impurity ions for forming a source/drain by annealing after forming first and second dielectric layers on the entire surface of the substrate.

### BRIEF DESCRIPTION OF THE DRAWINGS

The above objects, features and advantages of the disclosure will become more apparent from the following detailed description when taken in conjunction with the accompanying drawings, wherein:

FIG. 1a through ld are cross sectional views of a fabricating process of a semiconductor device according to the conventional art; and

FIGS. 2a through 2d are cross sectional view of a fabricating process of a semiconductor device according to the disclosure.

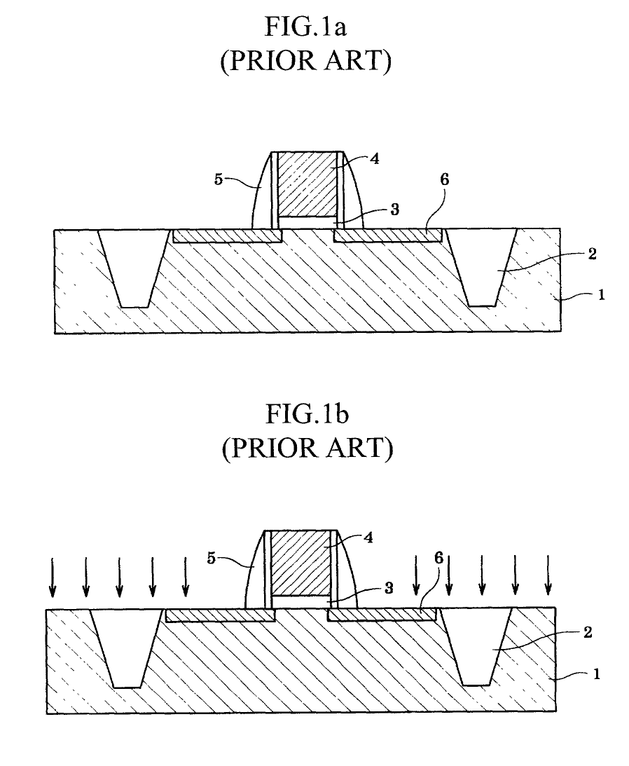

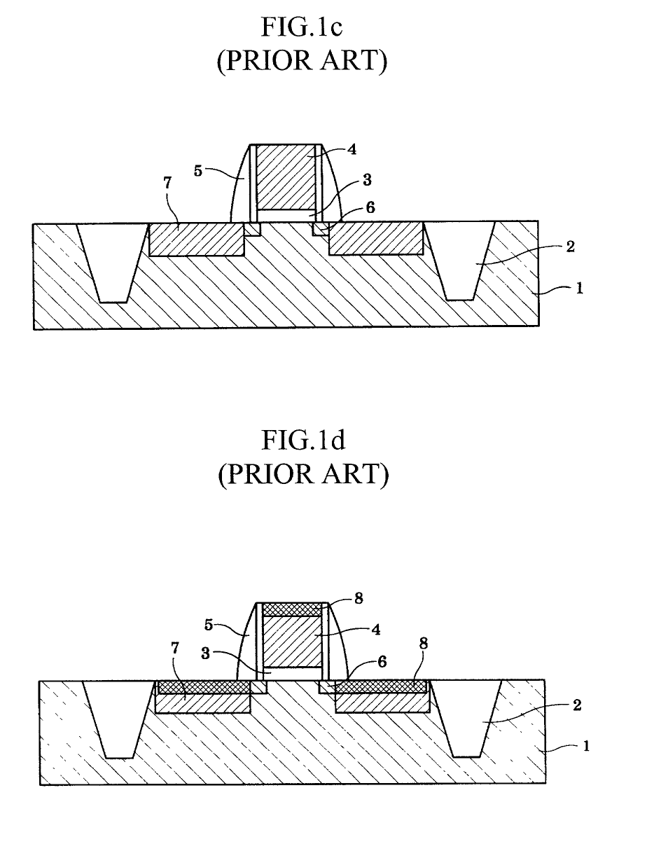

### DETAILED DESCRIPTION OF THE PRESENTLY PREFERRED EMBODIMENTS

One or more methods of fabricating a semiconductor device will now be described with reference to the accompanying drawings.

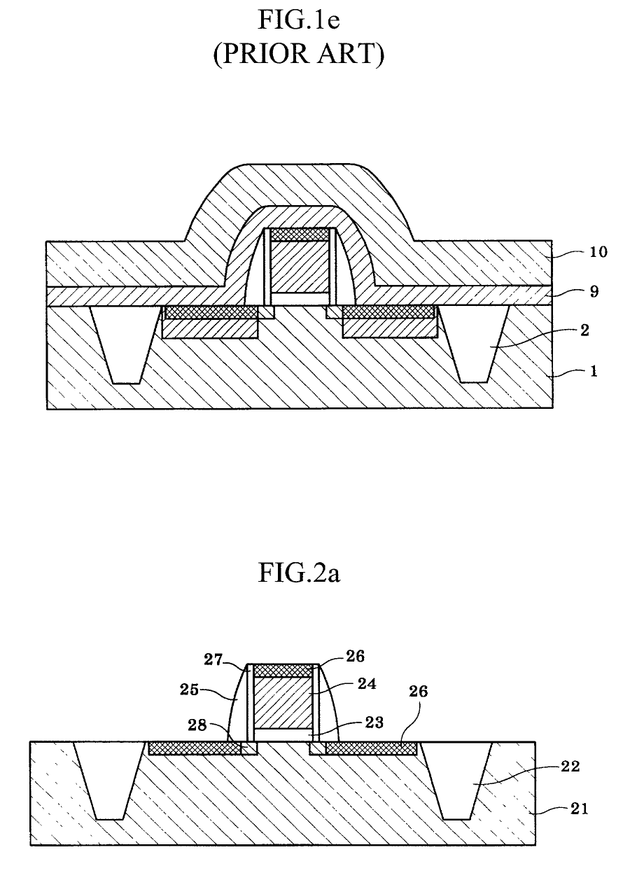

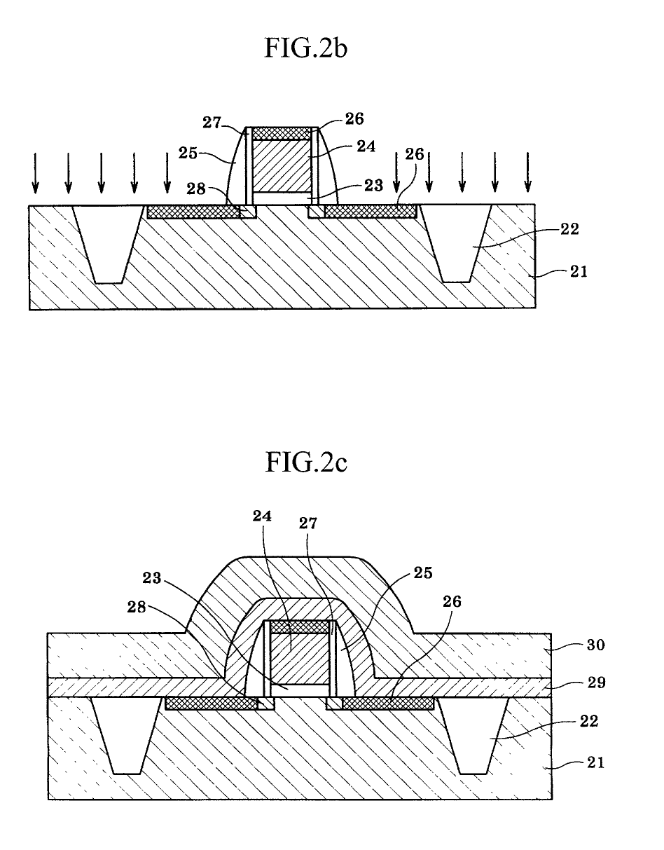

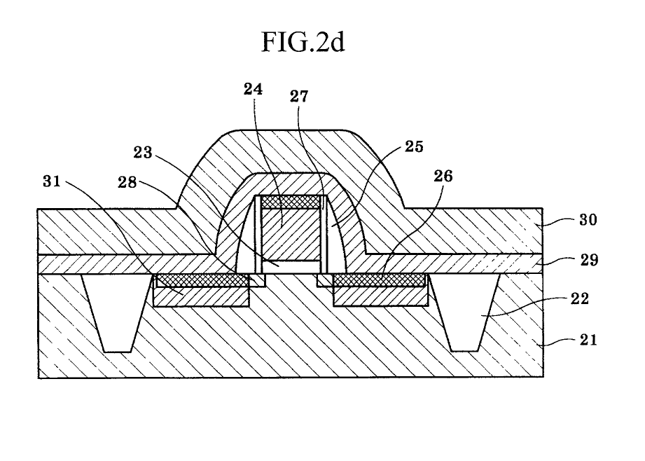

FIGS. 2a through 2d are cross sectional view of a fabricating process of a semiconductor device according to the disclosure.

First, as illustrated in FIG. 2a, a device isolation layer 22 is formed in a device isolation region of a semiconductor substrate 21 by a STI(shallow trench isolation) or LOCOS process.

Continually, a gate oxide layer 23 and a gate electrode 24 are formed in an active region defined by the device isolation layer 22, and then an ion implantation step for forming a LDD region 28 is carried out.

Then, a buffer oxide layer 27 and a gate sidewall 25 are formed on the sides of the gate electrode 24. Next, a refractory metal layer, for example, a cobalt layer, for silicide formation, is formed on the front surface, and then a silicide layer 26 is formed thereon by a thermal treatment.

In the step for forming a cobalt silicide layer, a first annealing is carried out by depositing a Co layer having a thickness of about 150 Å and a Ti layer having a thickness of about 150 Å, and a second annealing is carried out after removing unreacted residuals, for thereby forming stabilized cobalt silicide layer.

Continually, as illustrated in FIG. 2b, an ion implantation step for forming a source/drain is carried out.

Then, as illustrated in FIG. 2c, an ILD(inter-layer dielectric) layer 29 and a BPSG(boron phosphorus silicate glass) layer 30 are formed in order as first and second dielectric layers.

Next, as illustrated in FIG. 2d, a RTP(rapid thermal process) annealing step for activating the source/drain region is carried out at a temperature ranging from about 800 to about 950° C. to form a source/drain region 31.

In the method for fabricating a semiconductor device according to the present invention, it is not that silicide formation is carried out after a S/D junction, but that the SID junction is formed after the silicide formation, thus preventing the deactivation of the dopants.

Without carrying out an annealing step for deactivating dopants and flowing the BPSG layer, besides the annealing step for forming a SID junction and deactivating dopants, the disclosed method can achieve the formation of a proper junction, the prevention of excessive diffusion of dopants, the prevention of deactivation of dopants, and the planarization of the BPSG layer using a high temperature by a single annealing step.

The above-described methods for fabricating a semiconductor device according to the present invention has the following advantages.

The present invention can prevent the deactivation of dopants by firstly forming a silicide layer, and then carrying out an ion implantation step for forming a source/drain region and an annealing step for activating dopants after the formation of the ILD layer and the BPSG layer.

In addition, the disclosed method can increase the planarization characteristics of the BPSG layer used as an inter-layer dielectric layer, increase the reproducibility of the device by preventing the evaporation of dopants by using the ILD and BPSG layer, and simplifying the process and obtaining a sufficient process margin by reducing the number of annealing steps.

While the disclosed methods have been shown and described with reference to certain preferred embodiments thereof, it will be understood by those skilled in the art that various changes in form and details may be made therein without departing from the spirit and scope of the disclosure as defined by the appended claims.

What is claimed:

1. A method for fabricating a semiconductor device comprising:
defining an active region by forming a device isolation layer on a portion of a surface of a semiconductor substrate;
forming a gate electrode with two sides and a top surface in the active region and forming a LDD region on the surface of the substrate at both sides of the gate electrode leaving a remaining exposed portion of the substrate surface;
forming a gate sidewall at both sides of the gate electrode and forming a silicide layer on the top surface of the gate electrode and the remaining exposed portion of the substrate surface;
implanting impurity ions for forming a source/drain by using the gate electrode as a mask; and
activating the impurity ions for forming a source/drain by annealing after forming first and second dielectric layers over the silicide layer and substrate.

2. The method of claim 1, wherein the first dielectric layer is an ILD layer, and the second dielectric layer is a BPSG layer.

3. The method of claim 1, wherein, in the annealing step for activating the impurity ions, the flow of the second dielectric layer is occurred to be planarized.

4. The method of claim 1, wherein the annealing step is carried out by a RTP process at a temperature ranging from about 800 to about 950° C.

5. The method of claim 1, wherein, in the step for forming a silicide layer, a first annealing is carried out by depositing a Co layer with a thickness of about 150 Å and a Ti layer having a thickness of about 150 Å, and a second annealing is carried out after removing unreacted residuals, for thereby forming stabilized cobalt silicide layer.

6. A method for fabricating a semiconductor device comprising:
providing a semiconductor substrate having a surface;
defining an active region on the surface of the substrate by forming a device isolation layer on a portion of the surface of the substrate;
forming a gate electrode having two sides and a top surface in the active region;
forming a LDD region at both sides of the gate electrode and extending to a portion of the surface of the substrate leaving a remaining exposed portion of the surface of the substrate;
forming a gate sidewall at both sides of the gate electrode;
forming a silicide layer on the top surface of the gate electrode and extending to the remaining exposed portion of the surface of the substrate;
implanting impurity ions for forming a source/drain using the gate electrode as a mask;
forming first and second dielectric layers over the entire silicide layer; and
forming a source/drain by activating the impurity ions by annealing.

7. The method of claim 6, wherein the first dielectric is an ILD layer.

8. The method of claim 6 wherein, the second dielectric layer is a BPSG layer.

9. The method of claim 6, wherein the annealing step that results in the activating of the impurity ions results in a planarized flow of the second dielectric layer.

10. The method of claim 6, wherein the annealing step is carried out using a RTP process at a temperature ranging from about 800 to about 950° C.

11. The method of claim 6, wherein, during the step of forming a silicide layer, a first annealing is carried out by depositing a cobalt layer with a thickness of about 150 Å and a titanium layer having a thickness of about 150A, and a second annealing is carried out after removing unreacted residuals thereby forming a stabilized cobalt silicide layer.

12. A semiconductor device made in accordance with the method of claim 1.

13. A semiconductor device made in accordance with the method of claim 6.
